(19) United States
(12) Patent Application Publication
(10) Pub. No.: US 2016/0212839 A1
(43) Pub. Date: Jul. 21, 2016

(54) FLEXIBLE DISPLAY DEVICE

(71) Applicant: SAMSUNG DISPLAY CO., LTD., Yongin-si (KR)

(72) Inventors: Jin Hwan CHOI, Seoul (KR); Ju Chan PARK, Seoul (KR); Tae An SEO, Hwaseong-si (KR); Pil Suk LEE, Seoul (KR)

(21) Appl. No.: 14/872,206

(22) Filed: Oct. 1, 2015

(30) Foreign Application Priority Data
Jan. 16, 2015 (KR) 10-2015-0008163

(51) Int. Cl. H05K 1/02; H01L 27/32; H01L 51/52; H05K 1/11; H05K 1/18

(52) U.S. Cl. CPC H05K 1/028; H05K 1/117; H05K 1/181; H01L 51/5253; H01L 27/3276; H01L 2251/5338

(57) ABSTRACT

A flexible display device including a substrate including a display unit; a driver integrated chip (IC) connected to the display unit of the substrate, the driver IC supplying a driving voltage; a flexible printed circuit (FPC) attached to an outside portion of the substrate by a substrate pad part at an outer side of the driver IC; and a printed circuit board (PCB) attached to the FPC by a PCB pad part, the PCB transferring a driving voltage to the driver IC of the substrate through the FPC, wherein the outside portion of the substrate is bent to be attached to the FPC, and the FPC is bent in an opposite direction to a bending direction of the outside portion of the substrate to be attached to the PCB.

### CROSS-REFERENCE TO RELATED APPLICATION

Korean Patent Application No. 10-2015-0008163, filed on Jan. 16, 2015, in the Korean Intellectual Property Office, and entitled: “Flexible Display Device,” is incorporated by reference herein in its entirety.

### BACKGROUND

1. Field

Embodiments relate to a flexible display device.

2. Description of the Related Art

A flexible display device may be manufactured by using a flexible plastic substrate, e.g., low temperature poly silicone (LTPS), silicone, and/or polyimide. A pixel array may be formed on the flexible substrate and may include data lines and gate lines (that intersect each other), a thin film transistor (TFT), and a pixel electrode.

An outside portion of the flexible substrate may be provided with a driver IC for supplying a driving signal and a voltage to a pixel array. For example, the driver IC may include a gate driver IC and a data driver IC, and may be formed by a chip on glass (COG), chip on plastic (COP), or chip on film (COF) scheme.

A printed circuit board (PCB) having a driving circuit unit (other than the driver IC) may be connected to the flexible substrate by using a flexible printed circuit (FPC). The driver IC may be connected to a pad formed on the flexible substrate through a plurality of bumps, and may supply a driving voltage VCC, a ground voltage (GND), a data output signal, and/or an enable signal to the pixel array of the flexible substrate.

The above information disclosed in this Background section is only for enhancement of understanding of the background of the invention and therefore it may contain information that does not form the prior art that is already known in this country to a person of ordinary skill in the art.

### SUMMARY

Embodiments are directed to a flexible display device.

The embodiments may be realized by providing a flexible display device including a substrate including a display unit; a driver integrated chip (IC) connected to the display unit of the substrate, the driver IC supplying a driving voltage; a flexible printed circuit (FPC) attached to an outside portion of the substrate by a substrate pad part at an outer side of the driver IC; and a printed circuit board (PCB) attached to the FPC by a PCB pad part, the PCB transferring a driving voltage to the driver IC of the substrate through the FPC, wherein the outside portion of the substrate is bent to be attached to the FPC, and the FPC is bent in an opposite direction to a bending direction of the outside portion of the substrate to be attached to the PCB.

The outside portion of the substrate and the FPC may be bent in a hook form or an angled form.

The driver IC may be positioned at the outside portion of the substrate.

The outside portion of the substrate may be bent in a direction away from a surface on which the driver IC is positioned.

The outside portion of the substrate may be bent in a direction toward a surface on which the driver IC is positioned.

The substrate pad part may be positioned on a bent part of the substrate.

The substrate pad part may be positioned on a flat plate part of the substrate.

The substrate pad part may be positioned on a same surface of the substrate on which the driver IC is positioned.

The substrate pad part may be positioned on a surface of the substrate that is opposite to a surface of the substrate on which the driver IC is positioned.

The substrate pad part and the PCB pad part may be formed on opposing surfaces of a same portion of the FPC.

The substrate pad part and the PCB pad part may include conductive bumps.

The substrate pad part and the FPC may be electrically connected to each other by an anisotropic conductive film.

The FPC and the PCB pad part may be electrically connected to each other by an anisotropic conductive film.

The display unit may include a substrate, an organic light emitting diode layer on the substrate, and a thin film encapsulation layer on the organic light emitting diode layer.

### BRIEF DESCRIPTION OF THE DRAWINGS

Features will be apparent to those of skill in the art by describing in detail exemplary embodiments with reference to the attached drawings in which:

FIG. 1 illustrates a plan view schematically showing a connection structure before a flexible display device according to an exemplary embodiment is bent.

FIG. 2 illustrates a cross-sectional view schematically showing a connection structure after the flexible display device according to the exemplary embodiment is bent.

FIG. 3 illustrates a cross-sectional view schematically showing a connection structure after a flexible display device according to another exemplary embodiment is bent.

FIGS. 4(A) and 4(B) illustrate cross-sectional views schematically showing a connection structure after a flexible display device according to still another exemplary embodiment is bent.

FIG. 5 illustrates a diagram schematically showing a section of a substrate pad part in which a substrate according to an exemplary embodiment is connected to an FPC.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

The mention that any portion is present “over” or “on” another portion means that any portion may be directly formed on another portion or a third portion may be interposed between one portion and another portion.

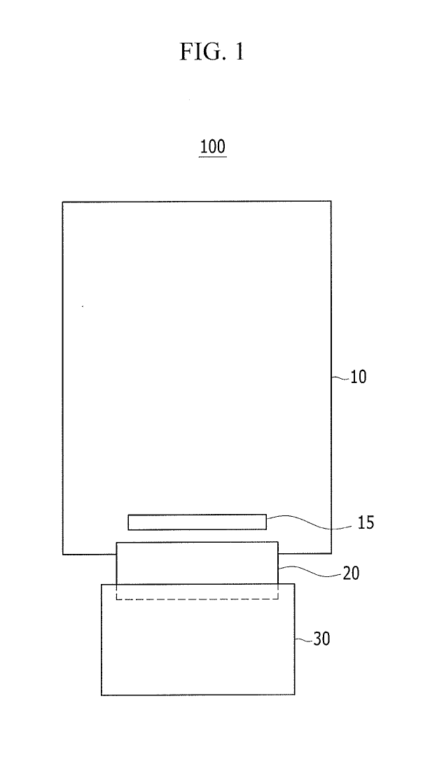

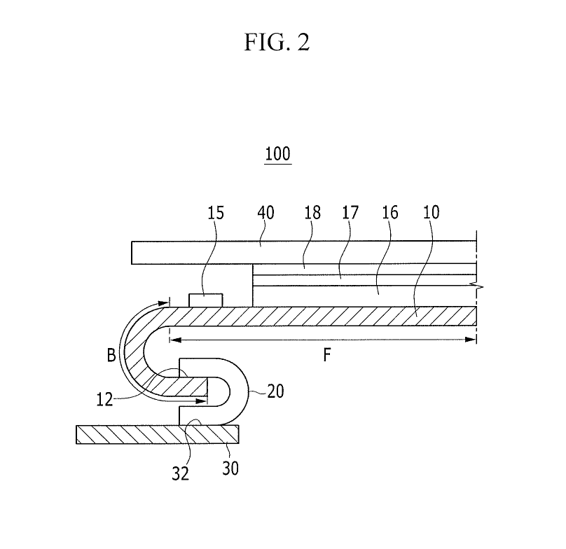

Hereinafter, a flexible display device according to an exemplary embodiment will be described with reference to FIGS. 1 and 2.

FIG. 1 illustrates a plan view schematically showing a connection structure before a flexible display device according to an exemplary embodiment is bent. FIG. 2 illustrates a cross-sectional view schematically showing a connection structure after the flexible display device according to the exemplary embodiment is bent.

Referring to FIGS. 1 and 2, a flexible display device 100 according to an exemplary embodiment may include, e.g., a substrate 10 and a driver integrated chip or circuit (IC) 15 positioned on the substrate 10. The driver IC 15 may be at an outside portion of the substrate 10, may be connected to a display unit of the substrate 10, and may supply a driving voltage. In an implementation, the outside portion of the substrate 10 at an outer side of the driver IC 15 may be attached with or to a flexible printed circuit (FPC) 20. The FPC 20 may be attached with or to a printed circuit board (PCB) 30 that transfers a driving voltage to the driver IC 15 on the substrate 10.

The substrate 10 may be a flexible substrate which is formed to have flexibility by, e.g., coating plastic materials such as low temperature poly silicone (LTPS), silicone, and/or polyimide. A pixel array may be formed on a display unit of the flexible substrate 10. In an implementation, the pixel array may include a plurality of data lines and a plurality of gate lines (intersecting each other), a thin film transistor, and a pixel electrode.

The outside portion of the substrate 10 may be provided with the driver IC 15, which may supply the driving voltage to the display unit of the substrate 10. The driver IC 15 may be a component in which a circuit chip or the like is mounted, in which the driving signal input from the PCB 30 may be transferred through the FPC 20, and may be converted by the driver IC 15 which is in turn supplied to the display unit. In an implementation, the driver IC may be disposed at the outside portion of the substrate or the driver IC may be mounted in the FPC.

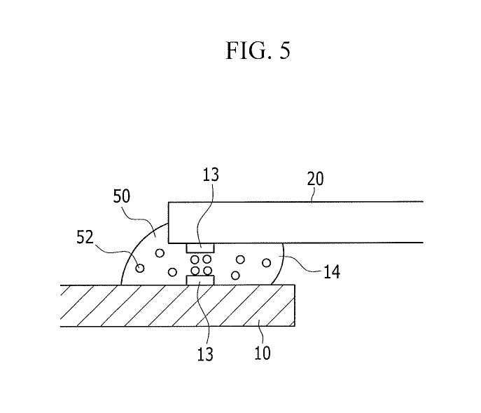

The FPC 20 may be attached to the outside portion 10 of the substrate 10 by way of the substrate pad part 12 at the outer side of the driver IC 15. As illustrated in FIG. 5, the substrate pad part 12 may include a plurality of e.g., conductive, bumps 13. For example, the bumps 13 may provided on the substrate 10 and facing inner side of the FPC 20, respectively, while facing each other. The bumps 13 of the substrate 10 and the FPC 20 may be electrically connected to each other at the attached portion of the substrate 10 and the FPC 20 by filling and hardening an anisotropic conductive film (ACF) 50 therebetween.

In an implementation, the PCB 30 may be attached to the FPC 20 by way of a PCB pad part 32 at a portion of the FPC 20 opposite to the portion of the FPC 20 that is attached to the substrate 10. The PCB pad part 32 may have a same structure as the substrate pad part 12. For example, the PCB pad part 32 may include the plurality of bumps 13 and the surface of the FPC 20 opposite to the PCB 30 may be provided with the bumps 13. The bumps 13 of the FPC 20 and of the PCB 30 may be electrically connected to each other at the attached portion of the FPC 20 and the PCB 30 by filling and hardening the anisotropic conductive film (ACF) 50 therebetween.

As illustrated in FIG. 2, the outside portion of the substrate 10 may be bent back in a hook form, and thus the substrate 10 may be attached to the FPC 20. In an implementation, the FPC 20 may be bent back in the hook form in a direction opposite to the bending direction of the outside portion of the substrate 10 to be attached to the PCB 30 (and the substrate 10). For example, the FPC 20 may be bent around and may surround an end of the substrate 10.

According to the exemplary embodiment, the outside portion of the substrate 10 may be bent in a direction opposite to, e.g., away from, the surface on which the driver IC 15 is positioned. The substrate pad part 12 may be positioned at the bending part B of the substrate 10, e.g., at the bent end of the substrate 10. In an implementation, the substrate pad part 12 may be positioned on the surface of the substrate 10 that is opposite to the surface on which the driver IC 15 is positioned. In other display device structures, a FPC may be attached to an outside portion of a substrate (which is not bent) and then the FPC may be bent, and the attached portion of the FPC and the substrate may be separated by a mechanical stress of the outside of the display device, thereby causing a contact defect phenomenon

According to the exemplary embodiment, the outside portion of the substrate 10 may be bent in the hook form to help reinforce the bonding between the bumps 13 of the substrate pad part 12, thereby helping to reduce and/or prevent the contact defect and to facilitate stable driving of the display device.

According to the exemplary embodiment, the flexible display device 100 may be an organic light emitting diode display device in which the display unit includes an organic light emitting diode (OLED). The flexible display device 100 may include a functional layer including the flexible substrate 10, an organic light emitting diode layer on the flexible substrate, a thin film encapsulation layer 16 covering and protecting the organic light emitting diode layer, and a polarization layer 17 and a touch panel 18 provided on the thin film encapsulation layer 16, and the like. In the functional layer, a transparent window layer 40 (which is an outermost portion of the display device) may be provided.

In an implementation, the flexible display device 100 may be, e.g., a liquid crystal display (LCD) device (in which a display unit includes a liquid crystal) or a plasma display device (in which the display unit includes a plasma display panel).

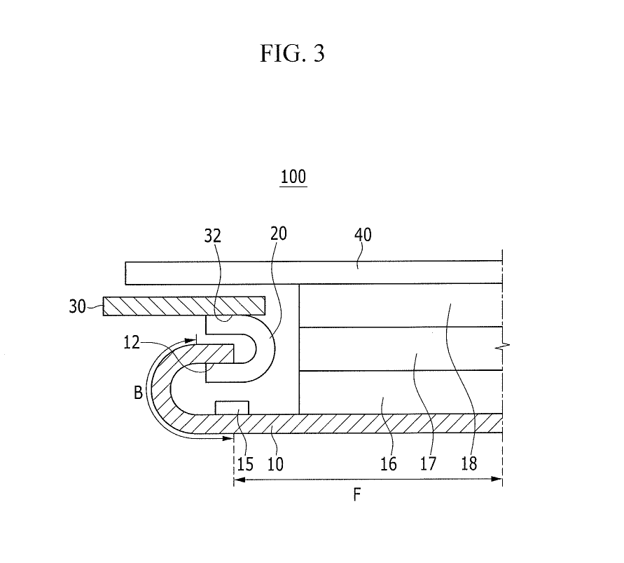

FIG. 3 illustrates a plan view schematically showing a connection structure after a flexible display device according to another exemplary embodiment is bent.

Referring to FIG. 3, the outside portion of the substrate 10 may be bent in the hook form and thus the substrate 10 may be attached to the FPC 20, like the exemplary embodiment of FIG. 2. Further, the FPC 20 may be bent in the hook form in a direction opposite to the bending direction of the outside portion of the substrate 10 to be attached to the PCB 30.

According to the present embodiment, the outside portion of the substrate 10 may be bent in the same surface direction as the surface on which the driver IC 15 is positioned. For example, the outside portion of the substrate 10 may be bent in or toward a light emitting surface direction of the display unit of the substrate 10. In an implementation, the substrate pad part 12 may be positioned at the bending part B of the substrate 10, e.g., at the bent end of the substrate 10, and may be positioned on the same surface of the substrate 10 on which the driver IC 15 is positioned.

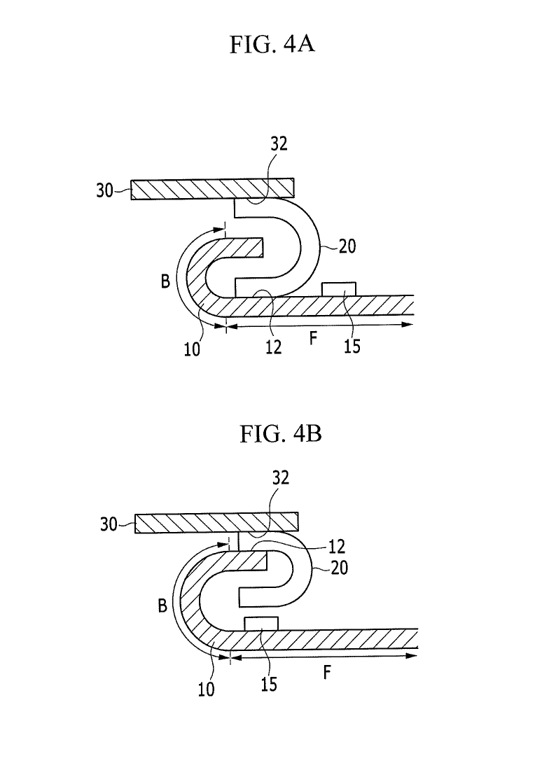

FIGS. 4(A) and 4(B) illustrate cross-sectional views schematically showing a connection structure after a flexible display device according to still another exemplary embodiment is bent. The functional layer (which includes the flexible substrate 10, the organic light emitting diode layer on the flexible substrate 10, the thin film encapsulation layer 16 covering and protecting the organic light emitting diode layer, the polarization layer 17 on the thin film encapsulation layer 16, the touch panel 18, and the like illustrated in FIGS. 2 and 3 and a transparent window layer 40 on the functional layer may have the same configuration, and therefore they are omitted in FIGS. 4A and 4B.

Referring to FIG. 4A, the outside portion of the substrate 10 may be bent in the same surface direction as the surface on which the driver IC 15 is positioned, e.g., may be bent back toward the driver IC 15. The substrate pad part 12 may be positioned at the flat plate part F of the substrate 10, e.g., inward from the bent end or portion of the substrate 10. In an implementation, the substrate pad part 12 may be positioned on the same surface of the substrate 10 on which the driver IC 15 is positioned. In an implementation, referring to FIG. 4B, the outside portion of the substrate 10 may be bent in the same surface direction as or toward the surface on which the driver IC 15 is positioned, and the substrate pad part 12 may be positioned at the bending part B of the substrate 10, e.g., on the bent end of the substrate 10. In an implementation, the substrate pad part 12 may be positioned on the opposite surface of the substrate 10 on which the driver IC 15 is positioned. In an implementation, the substrate pad part 12 and the PCB pad part 32 may be formed on both, e.g., opposing or opposite side, surfaces of the same portion or end of the FPC 20.

FIG. 5 illustrates a diagram schematically showing a section of a substrate pad part in which the substrate 10 is connected to the FPC 20. Referring to FIG. 5, the substrate pad part 12 may include the bump 13. The bumps 13 may be provided on the substrate 10 and the facing inner side of the FPC 20 to be attached to the substrate 10, respectively. The bumps 13 of the substrate 10 and the FPC 20 may be electrically connected to each other at the attached portion of the substrate 10 and the FPC 20 by filling and hardening the anisotropic conductive film (ACF) 50 therebetween.

The anisotropic conductive film 50 may include, e.g., a polymer 14 and a conductive particle 52 included in the polymer 14. The anisotropic conductive film 50 may be attached to the outside portion of the substrate 10 and the end of the FPC 20 at a melting temperature of, e.g., about 165° C. to about 175° C. During the hardening of the polymer 14 of the anisotropic conductive film 50, the conductive particle 52 may be disposed between the bumps 13 of the substrate 10 and the FPC and thus the substrate 10 may be electrically connected to the FPC 20 by the conductive particle 52.

By way of summation and review, the FPC may be bent in a rear direction of the flexible substrate, and the PCB may be positioned on a lower surface of the flexible substrate. The outside portion of the flexible substrate may be attached to the FPC by configuring a pad part in a plural forms of bumps to help reduce and/or prevent a contact failure with the driver IC, and the like. However, delamination may occur at a contact portion between the FPC and the flexible substrate due to a continuous or instantaneous external pressure.

The embodiments may provide a flexible display device having a structure in which an outside portion of a flexible substrate is connected to a printed circuit board (PCB) using a flexible printed circuit (FPC).

The embodiments may provide a flexible display device having advantages of helping to reduce and/or prevent a contact failure between a substrate and an FPC caused by an external mechanical stress, e.g., by bending an outside portion of a flexible substrate and the FPC respectively in a hook form to attach the FPC to the outside portion of the flexible substrate.

According to an exemplary embodiment, it is possible to prevent a contact failure between the substrate and the FPC caused the external mechanical stress, by bending the outside portion of the flexible substrate and the FPC in the hook form to attach the FPC to the outside portion of the flexible substrate.

As described above, in the flexible display device in accordance with an exemplary embodiment, it is possible to reduce and/or prevent the contact failure between the substrate and the FPC caused by the external mechanical stress, by bending the outside portion of the flexible substrate and the FPC in the hook form to attach the FPC to the outside portion of the flexible substrate in an entangled structure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

<Description of symbols>

| | |
|---|---|
| 100: Flexible display device | 10: Substrate |
| 12: Substrate pad part | 13: Bump |
| 14: Polymer | 15: Driver IC |
| 16: Thin film encapsulation layer | 17: Polarization layer |
| 18: Touch panel | 20: FPC |
| 30: PCB | 32: PCB pad part |
| 40: Window layer | 50: Anisotropic conductive film |
| 52: Conductive particle | B: Bending part |
| F: Flat plate part | |

What is claimed is:

1. A flexible display device, comprising:
a substrate including a display unit;
a driver integrated chip (IC) connected to the display unit of the substrate, the driver IC supplying a driving voltage;
a flexible printed circuit (FPC) attached to an outside portion of the substrate by a substrate pad part at an outer side of the driver IC; and
a printed circuit board (PCB) attached to the FPC by a PCB pad part, the PCB transferring a driving voltage to the driver IC of the substrate through the FPC,
wherein:
the outside portion of the substrate is bent to be attached to the FPC, and
the FPC is bent in an opposite direction to a bending direction of the outside portion of the substrate to be attached to the PCB.

2. The flexible display device as claimed in claim 1, wherein the outside portion of the substrate and the FPC are bent in a hook form or an angled form.

3. The flexible display device as claimed in claim 1, wherein the driver IC is positioned at the outside portion of the substrate.

4. The flexible display device as claimed in claim 1, wherein the outside portion of the substrate is bent in a direction away from a surface on which the driver IC is positioned.

5. The flexible display device as claimed in claim 1, wherein the outside portion of the substrate is bent in a direction toward a surface on which the driver IC is positioned.

6. The flexible display device as claimed in claim 1, wherein the substrate pad part is positioned on a bent part of the substrate.

7. The flexible display device as claimed in claim 1, wherein the substrate pad part is positioned on a flat plate part of the substrate.

8. The flexible display device as claimed in claim 1, wherein the substrate pad part is positioned on a same surface of the substrate on which the driver IC is positioned.

9. The flexible display device as claimed in claim 1, wherein the substrate pad part is positioned on a surface of the substrate that is opposite to a surface of the substrate on which the driver IC is positioned.

10. The flexible display device as claimed in claim 1, wherein the substrate pad part and the PCB pad part are formed on opposing surfaces of a same portion of the FPC.

11. The flexible display device as claimed in claim 1, wherein the substrate pad part and the PCB pad part include conductive bumps.

12. The flexible display device as claimed in claim 1, wherein the substrate pad part and the FPC are electrically connected to each other by an anisotropic conductive film.

13. The anisotropic conductive film as claimed in claim 1, wherein the FPC and the PCB pad part are electrically connected to each other by an anisotropic conductive film.

14. The anisotropic conductive film as claimed in claim 1, wherein the display unit includes:
a substrate,
an organic light emitting diode layer on the substrate, and
a thin film encapsulation layer on the organic light emitting diode layer.
